(19) United States
(12) Patent Application Publication
(10) Pub. No.: US 2024/0312981 A1
(43) Pub. Date: Sep. 19, 2024

(54) ESD PROTECTION CIRCUIT

(71) Applicant: Socionext Inc., Kanagawa (JP)

(72) Inventors: Yoshito UCHIHASHI, Yokohama-shi (JP); Masahiro GION, Yokohama-shi (JP); Toshihiro NAKAMURA, Yokohama-shi (JP)

(21) Appl. No.: 18/671,451

(22) Filed: May 22, 2024

Related U.S. Application Data
(63) Continuation of application No. PCT/JP2021/045117, filed on Dec. 8, 2021.

(51) Int. Cl. H01L 27/02

(52) U.S. Cl. CPC H01L 27/0285

(57) ABSTRACT

An ESD protection circuit includes: a protective element placed between VDD and VSS; an RC circuit; and an inverter connected to a node of the RC circuit at its input and to a node of the protective element at its output. The inverter includes a PMOS connected to VDD at its source and an NMOS connected to VSS at its source. The PMOS and the NMOS are connected in common to the node of the RC circuit at their gates and to the node of the protective element at their drains. The gate length of the PMOS is smaller than the gate length of the NMOS.

### CROSS-REFERENCE TO RELATED APPLICATIONS

This is a continuation of International Application No. PCT/JP2021/045117 filed on Dec. 8, 2021. The entire disclosure of this application is incorporated by reference herein.

### BACKGROUND

The present disclosure relates to an ESD protection circuit.

In recent years, with the increasingly enhanced performance of a semiconductor integrated circuit, the gate oxide films of transistors tend to be made thinner for improving the drive capabilities of the transistors. Due to the thinning of the gate oxide films, the resistance against breakdown caused by electrostatic discharge (ESD) is deteriorating. Therefore, to protect the semiconductor integrated circuit from ESD-caused breakdown, it has become important to place an ESD protection circuit.

An ESD protection circuit is provided in the following cases, for example:
1. when power supply is separated between digital circuits and analog circuits to prevent noise propagation,
2. when power supply is separated among a plurality of circuits so that some of the plurality of circuits can be put in a standby state, and
3. when there are a plurality of power supply systems in a semiconductor integrated circuit.

U.S. Pat. No. 7,969,699 (FIG. 1) discloses an example of the circuit configuration of an ESD protection circuit.

In general, a plurality of ESD protection circuits are placed in a semiconductor integrated circuit. Therefore, if a leak current is large in an ESD protection circuit, the power consumption of the semiconductor integrated circuit will increase. To avoid this, it is important to reduce the leak current in the ESD protection circuit in the steady state.

However, the ESD protection circuit disclosed in the cited patent document has a problem that reduction in the leak current in the steady state is not sufficient.

An objective of the present disclosure is providing an ESD protection circuit small in power consumption caused by a leak current.

### SUMMARY

According to the first mode of the present disclosure, an ESD protection circuit includes: a protective element having a first node, placed between a power supply terminal and a ground terminal; an RC circuit having a resistive element connected to the power supply terminal at one end and a capacitive element connected to the ground terminal at one end and to the other end of the resistive element at the other end, the other ends of the resistive element and the capacitive element being a second node; and an inverter connected to the second node of the RC circuit at its input and to the first node of the protective element at its output, wherein the inverter includes a p-type MOS transistor connected to the power supply terminal at its source, and an n-type MOS transistor connected to the ground terminal at its source, the p-type MOS transistor and the n-type MOS transistor are connected in common to the second node at their gates and to the first node at their drains, and a gate length of the p-type MOS transistor is smaller than a gate length of the n-type MOS transistor.

According to the above mode, when ESD occurs raising the potential of the power supply terminal, a large current flows between the drain and source of the p-type MOS transistor constituting the inverter because the gate length of the p-type MOS transistor is small. This swiftly raises the potential of the first node, whereby the protective element can swiftly let out the ESD-caused charge. That is, high ESD discharging characteristics are attained. On the other hand, in the steady state, a gate leak of the n-type MOS transistor can be reduced because the gate length of the n-type MOS transistor constituting the inverter is large. Since this can curb decrease in the potential of the second node, a leak current between the source and drain of the p-type MOS transistor can be reduced. That is, power consumption caused by a leak current in the ESD protection circuit can be greatly reduced. In this way, in the ESD protection circuit, increase in power consumption caused by a leak current can be curbed while the ESD discharging characteristics are kept high.

According to the second mode of the present disclosure, an ESD protection circuit includes: a protective element having a first node, placed between a power supply terminal and a ground terminal; an RC circuit having a resistive element connected to the power supply terminal at one end and a capacitive element connected to the ground terminal at one end and to the other end of the resistive element at the other end, the other ends of the resistive element and the capacitive element being a second node; and an inverter connected to the second node of the RC circuit at its input and to the first node of the protective element at its output, wherein the inverter includes a p-type MOS transistor connected to the power supply terminal at its source, and an n-type MOS transistor connected to the ground terminal at its source, the p-type MOS transistor and the n-type MOS transistor are connected in common to the second node at their gates and to the first node at their drains, and a thickness of a gate insulating film of the n-type MOS transistor is larger than a thickness of a gate insulating film of the p-type MOS transistor.

According to the above mode, in the steady state, a gate leak of the n-type MOS transistor can be reduced because the thickness of the gate insulating film of the n-type MOS transistor constituting the inverter is large. Since this can curb decrease in the potential of the second node, a leak current between the source and drain of the p-type MOS transistor constituting the inverter can be reduced. That is, power consumption caused by a leak current in the ESD protection circuit can be greatly reduced. In this way, in the ESD protection circuit, increase in power consumption caused by a leak current can be curbed while the ESD discharging characteristics are kept high.

According to the present disclosure, an ESD protection circuit small in power consumption caused by a leak current can be implemented.

### BRIEF DESCRIPTION OF THE DRAWINGS

FIG. 1 shows a circuit configuration of an ESD protection circuit according to an embodiment.

FIGS. 2A-2B show layout examples of transistors constituting an inverter, in which FIG. 2A shows a PMOS transistor and FIG. 2B shows an NMOS transistor.

FIG. 3 is a view for explaining a mechanism of occurrence of a leak current.

FIGS. 4A-4B show examples of cross-sectional structures of transistors constituting an inverter in an alteration, in which FIG. 4A shows a PMOS transistor and FIG. 4B shows an NMOS transistor.

### DETAILED DESCRIPTION

An embodiment of the present disclosure will be described hereinafter with reference to the accompanying drawings. Note that, in the following description, “VDD” denotes a power supply voltage, a power supply terminal, or a power supply itself, and “VSS” denotes a ground voltage, a ground terminal, or a ground power supply itself. Note also that a p-type MOS transistor is simply referred to as a PMOS transistor or a PMOS as appropriate, and an n-type MOS transistor is simply referred to as an NMOS transistor or an NMOS as appropriate.

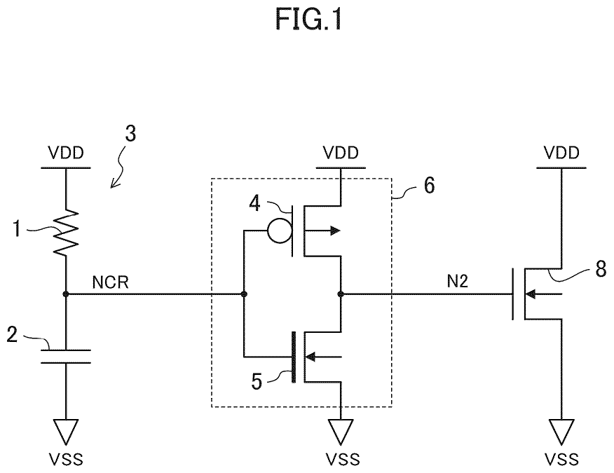

FIG. 1 shows a circuit configuration of an electrostatic discharge (ESD) protection circuit according to an embodiment. The ESD protection circuit shown in FIG. 1 includes: an RC circuit 3 constituted by a resistive element 1 and a capacitive element 2; an inverter 6 constituted by a PMOS transistor 4 and an NMOS transistor 5 formed on the principal plane of a semiconductor substrate; and an NMOS transistor 8 as an example of a protective element.

The resistive element 1 and the capacitive element 2 of the RC circuit 3 are connected in series between the power supply terminal VDD and the ground terminal VSS. That is, one end of the resistive element 1 is connected to the power supply terminal VDD, one end of the capacitive element 2 is connected to the ground terminal VSS, and the other end of the resistive element 1 and the other end of the capacitive element 2 are mutually connected. The mutually connected ends of the resistive element 1 and the capacitive element 2 are to be a connection node NCR. The resistive element 1 is constituted by at least one of a polysilicon resistance, a diffusion layer resistance, an interconnect resistance, and a well resistance, for example, formed on the principal plane of the semiconductor substrate. The capacitive element 2 is constituted by a transistor or an interconnect, for example.

The NMOS transistor 8, formed on the principal plane of the semiconductor substrate, is provided between the power supply terminal VDD and the ground terminal VSS. That is, the drain of the NMOS transistor 8 is connected to the power supply terminal VDD and the source thereof is connected to the ground terminal VSS. The gate of the NMOS transistor 8 is connected to a node N2. Note that the protective element is not limited to the NMOS transistor, but may be constituted by at least one of an NMOS transistor, a PMOS transistor, an NPN bipolar transistor, and a PNP bipolar transistor, for example, formed on the principal plane of the semiconductor substrate.

The inverter 6, connected to the connection node NCR at its input and to the node N2 at its output, controls the conduction state of the NMOS transistor 8 according to the potential at the connection node NCR of the RC circuit 3. In the inverter 6, the gates of the PMOS transistor 4 and the NMOS transistor 5 are mutually connected, and the drains thereof are mutually connected. The source of the PMOS transistor 4 is connected to the power supply voltage VDD, and the source of the NMOS transistor 5 is connected to the ground terminal VSS. The mutually connected gates of the PMOS transistor 4 and the NMOS transistor 5 are to be the input of the inverter 6 and connected to the connection node NCR. The mutually connected drains of the PMOS transistor 4 and the NMOS transistor 5 are to be the output of the inverter 6 and connected to the node N2.

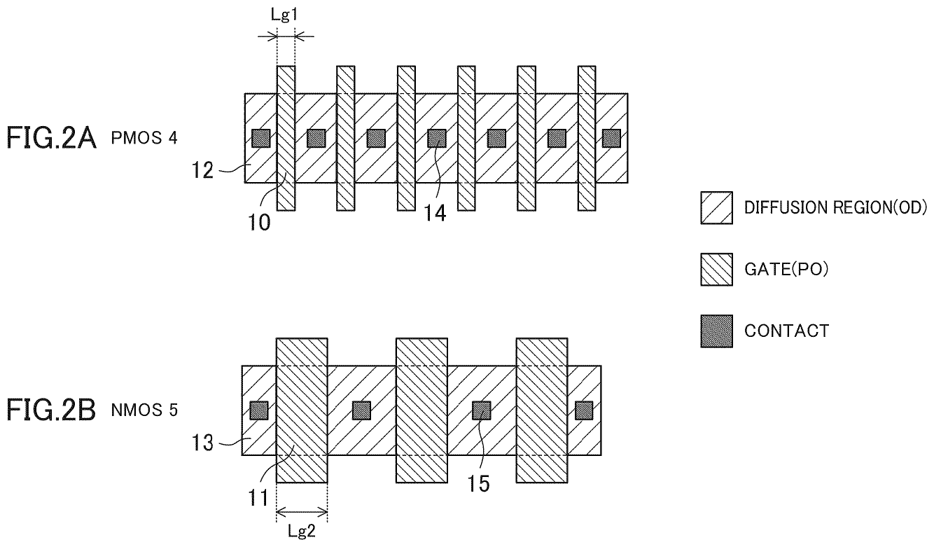

FIGS. 2A-2B are plan views showing layout examples of the transistors constituting the inverter 6, in which FIG. 2A shows a layout of the PMOS transistor 4 and FIG. 2B shows a layout of the NMOS transistor 5. As shown in FIG. 2A, the PMOS transistor 4 includes: a gate interconnect 10 that is to be the gate; diffusion regions 12 that are to be the source or the drain; and contacts 14 for connecting the source or the drain to upper-layer interconnects. Similarly, as shown in FIG. 2B, the NMOS transistor 5 includes: a gate interconnect 11 that is to be the gate; diffusion regions 13 that are to be the source or the drain; and contacts 15 for connecting the source or the drain to upper-layer interconnects.

Note here that the gate length Lg1 of the gate interconnect 10 of the PMOS transistor 4 is smaller than the gate length Lg2 of the gate interconnect 11 of the NMOS transistor 5.

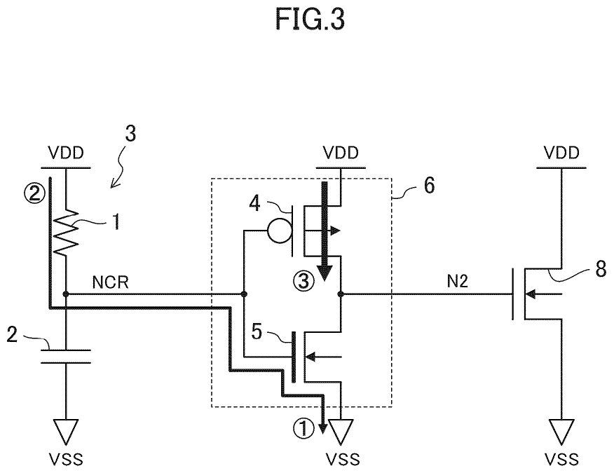

Referring to FIG. 3, the mechanism of occurrence of a leak current in the steady state in the ESD protection circuit of FIG. 1 will be described.

To attain high ESD characteristics, it is preferable to increase the size of the NMOS transistor 8. In this case, since the capacitance of the node N2 increases, the size of the transistors of the preceding inverter 6 also must be increased accordingly. This increases the leak current flowing from the gate of the NMOS transistor 5 of the inverter 6 to the ground terminal VSS (gate leak) (1). This leak current flows through the resistive element 1, whereby the potential of the connection node NCR decreases (2). This puts the PMOS transistor 4 of the inverter 6 in a weak ON state, causing a leak current to flow between the source and drain of the PMOS transistor 4 (3). In this way, in the ESD protection circuit, power consumption caused by a leak current increases in the steady state.

In this embodiment, the gate length Lg1 of the gate interconnect 10 of the PMOS transistor 4 is made smaller than the gate length Lg2 of the gate interconnect 11 of the NMOS transistor 5, whereby the increase in power consumption caused by a leak current is curbed while the ESD discharging characteristics of the ESD protection circuit are kept high.

### <Operation During ESD Protection>

When ESD occurs, the potential of the power supply terminal VDD rises. At this time, in the inverter 6, the gate-source voltage of the PMOS transistor 4 rises, causing a current to flow between the source and drain of the PMOS transistor 4 and raising the potential of the node N2. With the rise of the potential of the node N2, the gate-source voltage of the NMOS transistor 8 increases, causing a current to flow between the source and drain of the NMOS transistor 8. In this way, the ESD-caused charge can be let out via the NMOS transistor 8 from the power supply terminal VDD through the ground terminal VSS.

Also, when ESD occurs, the potential of the node NCR mildly rises due to the RC circuit 3. With the mild rise of the potential of the node NCR, in the inverter 6, the gate-source voltage of the PMOS transistor 4 gradually decreases, causing the current flowing between the source and drain of the PMOS transistor 4 to gradually decrease. This gradually reduces the potential of the node N2, thereby reducing the gate-source voltage of the NMOS transistor 8, and in the end, stopping the current flow between the source and drain of the NMOS transistor 8.

That is, the circuit configuration of FIG. 1 implements a scheme in which a current flows between the source and drain of the NMOS transistor 8 only for a temporary time period at the time of occurrence of ESD. This time period is determined depending on the resistance value of the resistive element 1 and the capacitance value of the capacitive element 2. It is therefore possible to pass a current between the source and drain of the NMOS transistor 8 for a desired time period from the occurrence of ESD.

In addition, with the reduced gate length Lg1 of the PMOS transistor 4, a larger current can be passed between the drain and source of the PMOS transistor 4. Since this swiftly raises the potential of the node N2 at the time of occurrence of ESD, the ESD-caused charge can be swiftly let out via the NMOS transistor 8. In other words, by reducing the gate length Lg1 of the PMOS transistor 4, the ESD discharging characteristics of the ESD protection circuit can be improved.

### <Operation in Steady State>

In the steady state, i.e., when no ESD occurs, the potential of the node NCR is VDD if no gate leak occurs in the NMOS transistor 5, and the leak current in the PMOS transistor 4 is kept low.

However, when the size of the NMOS transistor 8 is increased to attain high ESD characteristics, a leak current occurs between the source and drain of the PMOS transistor 4 according to the mechanism described above, resulting in an increase in power consumption caused by the leak current in the steady state.

In this embodiment, in which the gate length Lg2 of the NMOS transistor 5 is increased, the gate leak can be reduced. Since this can curb decrease in the potential of the node NCR, the leak current between the source and drain of the PMOS transistor 4 can be reduced. Therefore, the power consumption caused by the leak current in the ESD protection circuit can be greatly reduced.

As described above, according to this embodiment, when ESD occurs raising the potential of the power supply terminal VDD, a large current flows between the drain and source of the PMOS transistor 4 because the gate length Lg1 of the PMOS transistor 4 is small. This swiftly raises the potential of the node N2, whereby the NMOS transistor 8 can swiftly let out the ESD-caused charge. That is, high ESD discharging characteristics are attained. On the other hand, in the steady state, because the gate length Lg2 of the NMOS transistor 5 is large, the gate leak in the NMOS transistor 5 can be reduced. Since this can curb decrease in the potential of the node NCR, the leak current between the source and drain of the PMOS transistor 4 can be reduced. That is, the power consumption of the ESD protection circuit caused by the leak current can be greatly reduced. In this way, in the ESD protection circuit, increase in power consumption caused by the leak current can be curbed while the ESD discharging characteristics are kept high.

### (Alteration)

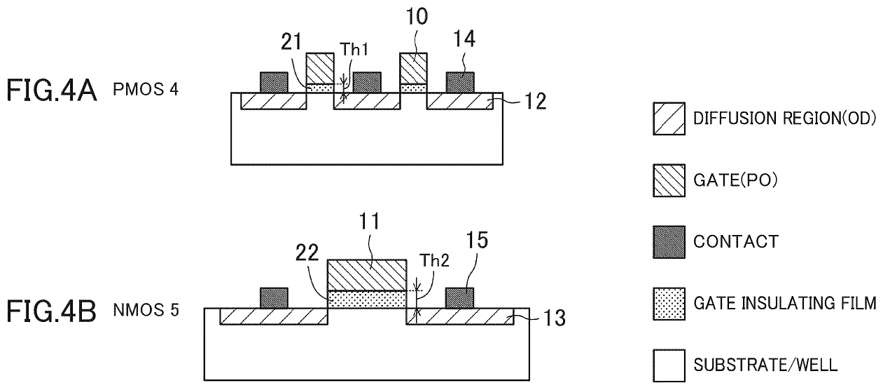

FIGS. 4A-4B are views showing cross-sectional structure examples of transistors constituting an inverter 6 of an ESD protection circuit of an alteration, in which FIG. 4A shows a cross-sectional structure of a PMOS transistor 4 and FIG. 4B shows a cross-sectional structure of an NMOS transistor 5. As shown in FIG. 4A, the PMOS transistor 4 includes: a gate interconnect 10 that is to be the gate; diffusion regions 12 that are to be the source or the drain; and contacts 14 for connecting the source or the drain to upper-layer interconnects. Similarly, as shown in FIG. 4B, the NMOS transistor 5 includes: a gate interconnect 11 that is to be the gate; diffusion regions 13 that are to be the source or the drain; and contacts 15 for connecting the source or the drain to upper-layer interconnects.

Note here that the thickness Th2 of a gate insulating film 22 of the NMOS transistor 5 is larger than the thickness Th1 of a gate insulating film 21 of the PMOS transistor 4.

As described above, when the size of the NMOS transistor 8 is increased to attain high ESD characteristics, for example, a leak current occurs between the source and drain of the PMOS transistor 4 according to the mechanism described above, resulting in an increase in power consumption caused by the leak current in the steady state.

In this alteration, in which the thickness Th2 of the gate insulating film 22 of the NMOS transistor 5 is increased, the gate leak of the NMOS transistor 5 can be reduced. Since this can curb decrease in the potential of the node NCR, the leak current between the source and drain of the PMOS transistor 4 can be reduced. Therefore, the power consumption caused by the leak current in the ESD protection circuit can be greatly reduced.

Note that this alteration may be combined with the above-described embodiment. That is, in the inverter 6 of the ESD protection circuit, the gate length Lg1 of the gate interconnect 10 of the PMOS transistor 4 is made smaller than the gate length Lg2 of the gate interconnect 11 of the NMOS transistor 5, and moreover the thickness Th2 of the gate insulating film 22 of the NMOS transistor 5 may be made larger than the thickness Th1 of the gate insulating film 21 of the PMOS transistor 4.

According to the present disclosure, an ESD protection circuit small in leak current can be implemented. The present disclosure is therefore useful for implementing a low-power semiconductor chip, for example.

1. An ESD protection circuit, comprising:
a protective element having a first node, placed between a power supply terminal and a ground terminal;
an RC circuit having a resistive element connected to the power supply terminal at one end and a capacitive element connected to the ground terminal at one end and to the other end of the resistive element at the other end, the other ends of the resistive element and the capacitive element being a second node; and
an inverter connected to the second node of the RC circuit at its input and to the first node of the protective element at its output,
wherein
the inverter includes
a p-type MOS transistor connected to the power supply terminal at its source, and
an n-type MOS transistor connected to the ground terminal at its source,
the p-type MOS transistor and the n-type MOS transistor are connected in common to the second node at their gates and to the first node at their drains, and
a gate length of the p-type MOS transistor is smaller than a gate length of the n-type MOS transistor.

2. The ESD protection circuit of claim 1, wherein
a thickness of a gate insulating film of the n-type MOS transistor is larger than a thickness of a gate insulating film of the p-type MOS transistor.

3. The ESD protection circuit of claim 1, wherein
the protective element is a second n-type MOS transistor connected to the first node at its gate, to the ground terminal at its source, and to the power supply terminal at its drain.

4. An ESD protection circuit, comprising:
a protective element having a first node, placed between a power supply terminal and a ground terminal;
an RC circuit having a resistive element connected to the power supply terminal at one end and a capacitive element connected to the ground terminal at one end and to the other end of the resistive element at the other end, the other ends of the resistive element and the capacitive element being a second node; and
an inverter connected to the second node of the RC circuit at its input and to the first node of the protective element at its output,
wherein
the inverter includes
a p-type MOS transistor connected to the power supply terminal at its source, and
an n-type MOS transistor connected to the ground terminal at its source,
the p-type MOS transistor and the n-type MOS transistor are connected in common to the second node at their gates and to the first node at their drains, and
a thickness of a gate insulating film of the n-type MOS transistor is larger than a thickness of a gate insulating film of the p-type MOS transistor.

5. The ESD protection circuit of claim 4, wherein
the protective element is a second n-type MOS transistor connected to the first node at its gate, to the ground terminal at its source, and to the power supply terminal at its drain.
